(19) United States
(12) Patent Application Publication
(10) Pub. No.: US 2024/0280607 A1
(43) Pub. Date: Aug. 22, 2024

(54) ELECTRICAL TEST CONTACT TERMINAL FOR A PIN-TYPE DEVICE LEAD

(71) Applicant: JF MICROTECHNOLOGY SDN. BHD., Petaling Jaya (MY)

(72) Inventors: Wei Kuong FOONG, Petaling Jaya (MY); Kok Sing GOH, Petaling Jaya (MY); Shamal MUNDIYATH, Petaling Jaya (MY); Eng Kiat LEE, Petaling Jaya (MY)

(73) Assignee: JF MICROTECHNOLOGY SDN. BHD., Petaling Jaya (MY)

(21) Appl. No.: 18/582,132

(22) Filed: Feb. 20, 2024

(30) Foreign Application Priority Data
Feb. 20, 2023 (MY) PI 2023000870

(51) Int. Cl. G01R 1/04; G01R 31/28; H01R 12/71; H01R 13/115

(52) U.S. Cl. CPC G01R 1/0416; G01R 31/2886; H01R 12/718; H01R 13/115; H01R 2201/20

(57) ABSTRACT

An electrical contact terminal in a testing apparatus that is provided with dual contacts, one for force and the other for sense. This allows both force and sense contacts to establish an electrical connection with the device pin, even when the device pin has a lateral deviation from its desired position. The present invention also teaches of a method of assembly of the contact terminal that overcomes the space constraint that results from having two contacts instead of just one in the given space.

### FIELD OF INVENTION

The present invention relates generally to an electrical test contact terminal for an integrated circuit (IC) device, and more specifically to such a contact terminal for an IC device with pin-type leads.

### BACKGROUND OF INVENTION

Integrated circuit (IC) devices are tested to evaluate their performance as part of the manufacturing process. When testing IC devices with needle or pin-type leads, the pins of the devices have to be electrically connected to the contacts of the test terminal. The problem is, the pin-type leads are usually installed or soldered independently onto the devices as a distinct part of the manufacturing process. This causes the positional accuracy and dimensional tolerances of the device pin to vary widely. All this makes establishing good electrical connection between the device pin and the test terminal a challenge for traditional designs of electrical test contact terminals. Some of these tests also require very high electrical currents to run through these electrical contact terminals, which makes the quality of the electrical connection even more crucial.

One solution for an electrical contact terminal, such as that described in U.S. Pat. No. 10,826,217 (Foong, et al), is a clamp design comprising a pair of contacts that rely on elastomers to provide a clamping force on the device pin as it is lowered during a test. The pair of contacts comprise a force contact and a sense contact, each of which perform different test functions. It is imperative for both contacts to have a good electrical connection with the device pin during a test. One problem with this solution is that the device pin may have a lateral deviation, meaning it can stray laterally from a desired or optimal position. In some cases, the lateral deviation or offset can be up to 0.1 mm to 0.5 mm. When this happens, the device pin sometimes only electrically connects with one of the contacts, and not the other. This leads to either a failed test or inaccurate results. Another problem that can occur is pitching (at an angle from the vertical axis) of the device pin. In some cases, pitching of the device pin can be as much as 2.6 mm or more. The combination of lateral deviation and pitching makes the electrical connection between the contacts and the device pin even more challenging.

What is needed in the art is an electrical test contact terminal in an IC device testing apparatus that provides a good electrical connection even when the device pin has a lateral deviation and pronounced pitching, and strays from a desired position.

### SUMMARY OF INVENTION

The present invention seeks to overcome the aforementioned disadvantages by providing an electrical contact terminal in a testing apparatus that is provided with dual contacts arranged closely and in parallel, one for force and the other for sense. This allows both force and sense contacts to establish an electrical connection with the device pin, even when the device pin has a lateral deviation from its desired position. The present invention also teaches of a method of assembly of the contact terminal that overcomes the space constraint that results from having two contacts instead of just one in the given space.

This invention thus relates to an electrical contact terminal in a testing apparatus for detachably connecting with an integrated circuit (IC) device pin, comprising: a force contact extending along a longitudinal axis (YY) between a first and a second end and having a forked pair of arms extending towards its first end, said arms adapted to receive the device pin in between thereof and having an inward bias so as to establish a good electrical connection with the device pin, and further having a means of establishing an electrical connection with a load board of the testing apparatus, said means extending towards its second end; a sense contact also extending along the longitudinal axis (YY) between a first and a second end and having a forked pair of arms extending towards its first end, said arms adapted to receive the device pin in between thereof and having an inward bias so as to establish a good electrical connection with the device pin, and further having a means of establishing an electrical connection with a load board of the testing apparatus, said means extending towards its second end, whereby as the device pin is lowered towards the testing apparatus, it connects with at least one arm of the force contact and at least one arm of the sense contact. In this way, the device pin always establishes a good electrical connection with both the force and sense contacts during a test. Each of the force and sense contacts with its upper forked pair of inwardly biased arms acts like a clamp on the device pin during a test. Each pair of arms are provided on an inside surface with a relief cavity close to their upper ends, said relief cavity allowing only a portion of the inside surface near the upper end of the arms to be in contact with the device pin. This significantly reduces any stresses on the contact arms caused by the device pin having a lateral or angular deviation.

This invention also relates to an electrical contact terminal in a testing apparatus for detachably connecting with an IC device pin, wherein the force contact's means of establishing an electrical connection with the load board comprises a pair of legs extending towards its second end, and wherein the sense contact's means of establishing an electrical connection with the load board also comprises a pair of legs extending towards its second end, said legs having an outward bias when snugly inserted into contact holes of a load board of the testing apparatus. Each of the force and sense contacts is also provided with a shoulder comprising two lateral protrusions protruding on opposite sides of the contact and located between its pair of arms and pair of legs.

The force and sense contact's means of establishing an electrical connection with the load board further comprises a top plate, a middle plate and a bottom plate. The bottom plate is provided with holes through which holes the pair of legs, but not the shoulders of both the force and sense contacts, can pass. The middle plate is provided with holes sized so that the shoulders can just snugly pass through. The top plate is provided with holes through which holes the pair of arms, but not the shoulders of both the force and sense contacts, can pass. During an assembly of each of the force contact and sense contact, the pair of legs is inserted through the middle plate holes and into the bottom plate holes, within which bottom plate holes their outward bias grips a side wall of the bottom plate holes. The shoulders rest on a top surface of the bottom plate and are held in lateral position within the middle plate holes. The top plate is then lowered onto the assembly, with the top plate holes being threaded by the pair of arms, and the top plate securing the shoulders so that the contacts are held securely in place at their shoulders, with the arms allowed to flex as required during a test.

In a preferred embodiment, the top plate holes, middle plate holes and bottom plate holes are rectangular holes with extremely precise corners and edges that are formed using non-contact machining techniques such as laser cutting. The non-contact machining techniques allow the rectangular holes to be formed without any machining burr or cutter radius. This is important for allowing very precise and accurate rectangular holes to be formed close to one another, thereby allowing two contacts to be located close to each other. The non-contact machining techniques also result in very accurate dimensions of the holes, thereby ensuring that the contacts are well fitted to the load board, as well as precisely positioned for optimal receiving of the device pins.

This invention thus provides an elegant solution to the problem of a device pin with lateral deviation from a desired position not establishing electrical connection with both the force and sense contacts. The provision of dual contacts, one for force and the other for sense, ensures that the device pin will always establish electrical connection with both the force and the sense contacts during a test.

The problem of space constraint that is derived from placing two contacts so close to each other is further solved using the assembly method of the contacts, wherein three layers of plates (bottom, middle and top) with holes of different sizes in each in conjunction with a shoulder located on each contact, and also the non-contact machining technique of the rectangular plate holes, allows both contacts to be assembled in the limited available space.

Other objects and advantages will be more fully apparent from the following disclosure and appended claims.

### BRIEF DESCRIPTION OF DRAWINGS

FIG. 1 shows a perspective view of a contact in an embodiment of the present invention.

FIG. 2 shows a front view of a contact in an embodiment of the present invention.

FIG. 3 shows a side view of a contact in an embodiment of the present invention.

FIG. 4 shows a perspective view of dual contacts in an embodiment of the present invention.

FIG. 5 shows a front view of dual contacts in an embodiment of the present invention.

FIG. 6 shows a perspective view of dual contacts engaging a device pin in an embodiment of the present invention.

FIG. 7 shows a perspective view of dual contacts engaging a laterally deviated device pin in an embodiment of the present invention.

FIG. 8 shows a perspective view of a bottom plate in an embodiment of the present invention.

FIG. 9 shows a cross-sectional view of a bottom plate in an embodiment of the present invention.

FIG. 10 shows a perspective view of a bottom and middle plate in an embodiment of the present invention.

FIG. 11 shows a cross-sectional view of a bottom and middle plate in an embodiment of the present invention.

FIG. 12 shows a perspective view of a bottom and middle plate with contacts inserted in an embodiment of the present invention.

FIG. 13 shows a cross-sectional view of a bottom and middle plate with contacts inserted in an embodiment of the present invention.

FIG. 14 shows a perspective view of a fully assembled contact terminal in an embodiment of the present invention.

FIG. 15 shows a cross-sectional view of a fully assembled contact terminal in an embodiment of the present invention.

### REFERENCE LIST

Force contact (10)
Force contact first end (102)
Force contact second end (104)
Force contact first arm (12)
Force contact second arm (13)
Force contact shoulder (14)
Force contact first leg (15)
Force contact second leg (16)
Force contact relief cavity (17)
Sense contact (20)
Sense contact first end (202)
Sense contact second end (204)
Sense contact first arm (22)
Sense contact second arm (23)
Sense contact shoulder (24)
Sense contact first leg (25)
Sense contact second leg (26)
Sense contact relief cavity (27)
Top plate (30)
Top plate holes (32)
Middle plate (40)
Middle plate holes (42)
Bottom plate (50)
Bottom plate holes (52)
Bottom plate top surface (54)
Device pin (60)

### DETAILED DESCRIPTION OF INVENTION

It should be noted that the following detailed description is directed to an electrical contact terminal for a semiconductor device testing apparatus, and is not limited to any particular size or configuration but in fact a multitude of sizes and configurations within the general scope of the following description.

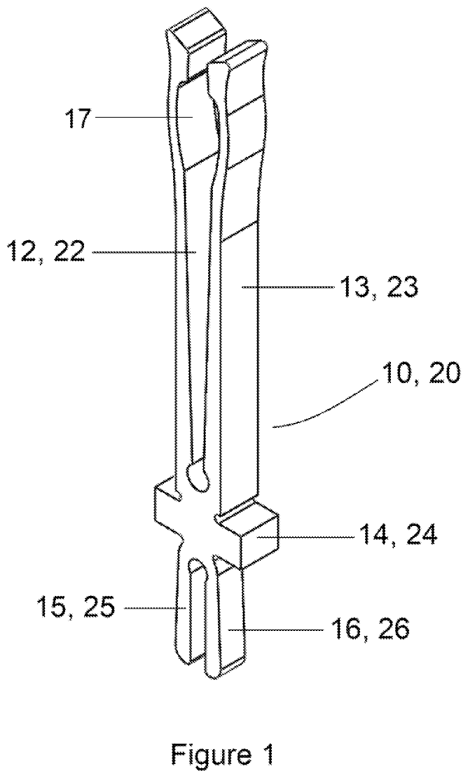

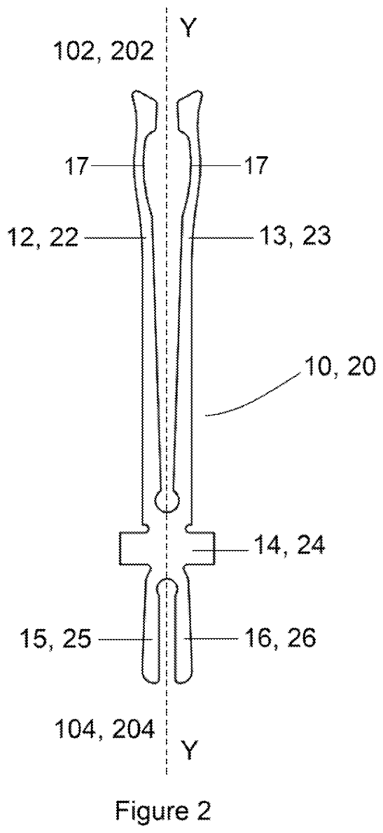

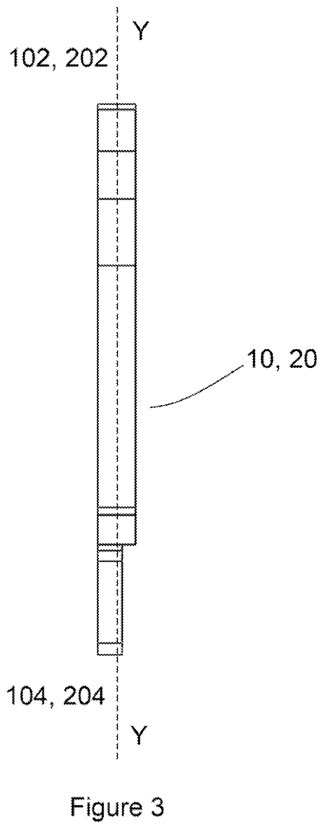

FIGS. 1, 2 and 3 show different views of a contact (10, 20) of this invention. One inventive feature of this invention is using two of these contacts together in a dual side-by-side arrangement, one to act as a force contact (10), and the other to act as a sense contact (20) during a test. These contacts (10, 20) are however identical, and so only one contact is shown in FIGS. 1 through 3 in order to better illustrate its details. Referring to FIGS. 1 through 3, there is shown that the contact (10, 20) is elongated along a Y-Y (or vertical) axis, having a first end (102, 202) and a second end (104, 204). A forked pair of arms comprising a first arm (12, 22) and a second arm (13, 23) extend towards the first end (102, 202). This pair of arms is flexible to an extent, so that when a device pin is lowered onto it during a test, each arm (12, 13, 22, 23) is able to flex enough to receive the device pin between the arms. The positioning and flex of each arm also causes each arm to press against the device pin once it is received between the arms, thus improving an electrical connection between the device pin and the contact (10, 20).

Each pair of arms (12, 13 and 22, 23) are provided with a relief cavity (17, 27), which is a concave curve on an inside surface of each arm, close to their upper ends. This relief cavity (17, 27) allows only a portion of the inside surface near the upper end of the arms to be in contact with the device pin. This significantly reduces any stresses on the contact arms (12, 13, 22, 23) caused by the device pin having a lateral or angular deviation.

Still referring to FIGS. 1 through 3, there is also provided on each contact a pair of legs comprising a first leg (15, 25) and a second leg (16, 26), both extending towards the second end (104, 204). This pair of legs (15, 16, 25, 26) comprise the contact's means of establishing an electrical connection with a load board of the testing apparatus. The legs have an outward bias when snugly inserted into contact holes of the load board. On an intermediate point of the contact (10, 20), and from where the pair of arms and pair of legs extend, is provided a shoulder (14, 24). The shoulder (14, 24) comprises two lateral protrusions protruding on opposite sides of the contact.

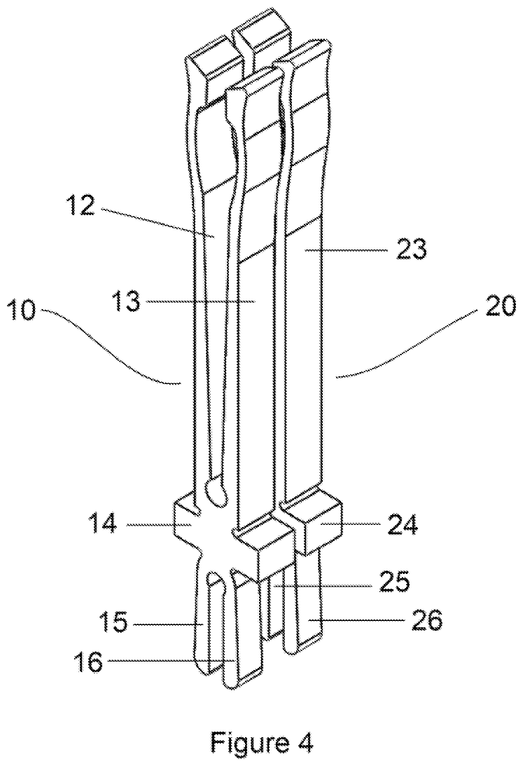

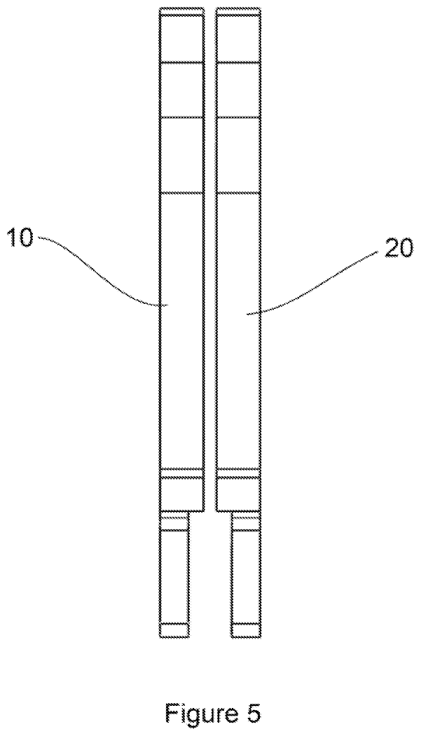

Referring now to FIGS. 4 and 5, which show different views of dual contacts in a side-by-side arrangement in an embodiment of this invention, there can be seen a force contact (10) and a sense contact (20). The force contact (10) is elongated along a Y-Y axis, having a first end (102) and a second end (104). A forked pair of arms comprising a first arm (12) and a second arm (13) extend towards the first end (102). This pair of arms is flexible to an extent, so that when a device pin is lowered onto it during a test, each arm (12, 13) is able to flex enough to receive the device pin between the arms. The positioning and flex of each arm also causes each arm to press against the device pin once it is received between the arms, thus improving an electrical connection between the device pin and the force contact (10). There is also provided on the force contact a pair of legs comprising a first leg (15) and a second leg (16), both extending towards the second end (104). This pair of legs (15, 16) comprise the force contact's means of establishing an electrical connection with a load board of the testing apparatus. The legs (15, 16) have an outward bias when snugly inserted into contact holes of the load board. On an intermediate point of the force contact (10), and from where the pair of arms (12, 13) and pair of legs (15, 16) extend, is provided a shoulder (14). The shoulder (14) comprises two lateral protrusions protruding on opposite sides of the force contact.

Still referring to FIGS. 4 and 5, there is also seen a sense contact (20), which is also elongated along a Y-Y axis, and having a first end (202) and a second end (204). A forked pair of arms comprising a first arm (22) and a second arm (23) extend towards the first end (202). This pair of arms is flexible to an extent, so that when a device pin is lowered onto it during a test, each arm (22, 23) is able to flex enough to receive the device pin between the arms. The positioning and flex of each arm also causes each arm to press against the device pin once it is received between the arms, thus improving an electrical connection between the device pin and the sense contact (20). There is also provided on the sense contact a pair of legs comprising a first leg (25) and a second leg (26), both extending towards the second end (204). This pair of legs (25, 26) comprise the sense contact's means of establishing an electrical connection with a load board of the testing apparatus. The legs (25, 26) have an outward bias when snugly inserted into contact holes of the load board. On an intermediate point of the sense contact (20), and from where the pair of arms (22, 23) and pair of legs (25, 26) extend, is provided a shoulder (24). The shoulder (24) comprises two lateral protrusions protruding on opposite sides of the sense contact.

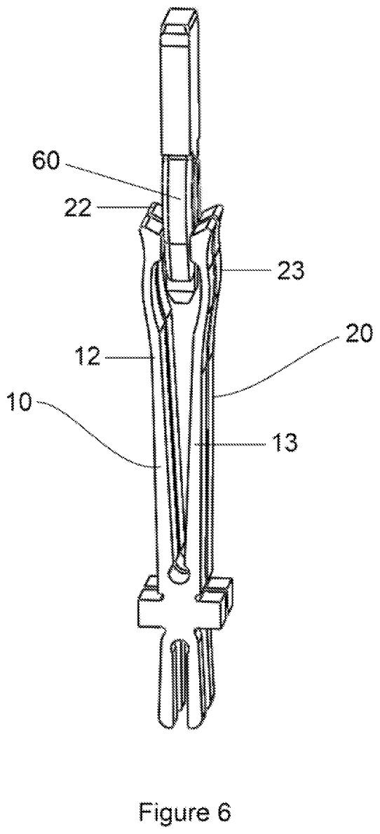

FIG. 6 shows a view of the dual contacts arrangement of this invention engaging a device pin (60) that is at its optimal lateral position, that is the device pin (60) is received right between the arms (12, 13, 22, 23) of the force (10) and sense (20) contacts.

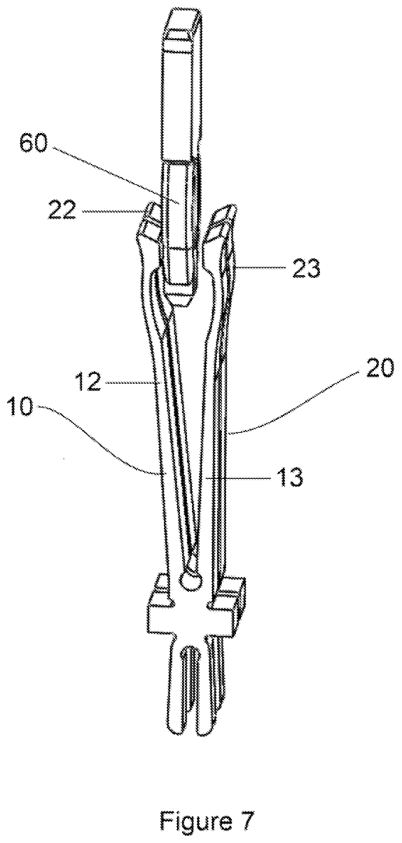

FIG. 7 shows a view of the dual contacts arrangement of this invention engaging a device pin (60) that is not at its optimal lateral position, that is the device pin (60) is offset laterally and when lowered towards the contacts (10, 20), does not slip right between the arms (12, 13, 22, 23) of the force (10) and sense (20) contacts. In this case of lateral deviation of the device pin (60), the dual arrangement of the force (10) and sense (20) contacts still allows the device pin (60) to establish electrical connection with at least one arm of both the force contact (10) and sense contact (20).

The provision of dual contacts described above, one for force and the other for sense, ensures that the device pin will always establish electrical connection with both the force and the sense contacts during a test.

### Method of Assembly

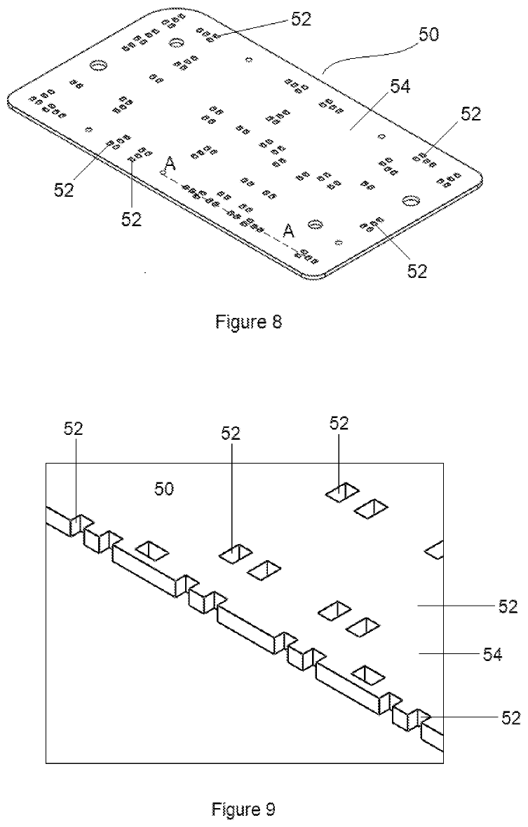

In order to achieve the dual contact arrangement described above, with the force and sense contacts being very close to each other, a new method of assembly for the force and sense contacts had to be invented. Known techniques of assembling electrical contacts to the load board of the testing apparatus are unable to accommodate very closely placed contacts, such as the dual contacts described above. For the arrangement and closeness of the force and sense contacts of this invention, the method of assembly with the load board is now described with reference to FIGS. 8 through 15.

FIGS. 8 and 9 show, respectively, a perspective view and a zoomed-in cross-sectional (A-A) view of a bottom plate (50) in an embodiment of the present invention. This is the first step in the assembly method, where the bottom plate (50) is fixed to, say, an installation jig (not shown). The bottom plate (50) is provided with rectangular holes (52) specifically positioned and sized to allow the contact legs to thread through. The bottom plate (50) is also provided with a top surface (54).

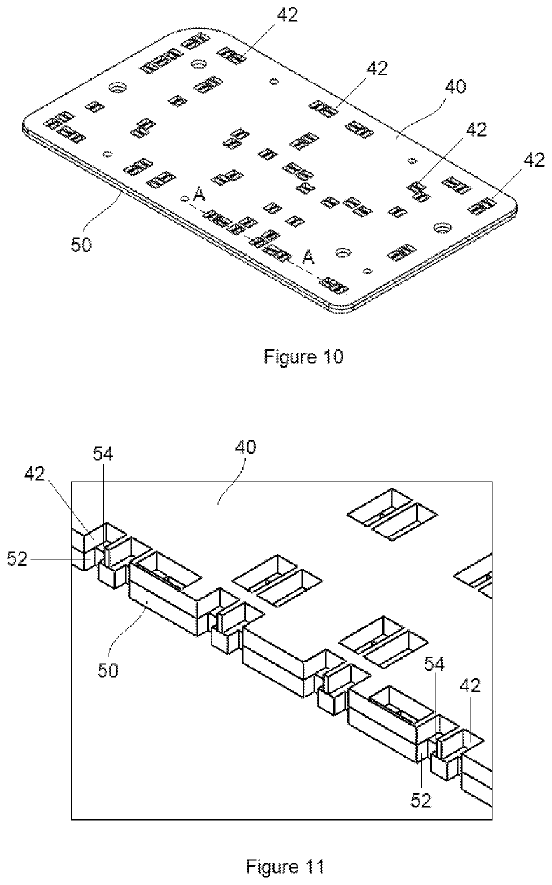

FIGS. 10 and 11 show, respectively, a perspective view and a zoomed-in cross-sectional (A-A) view of a middle plate (40) and bottom plate (50) in an embodiment of the present invention. This is the second step in the assembly method, where the middle plate (40) has been placed flush on top of the bottom plate (50). The middle plate (40) is also provided with rectangular holes (42), which mostly correspond to the positions of the bottom plate holes (52). The middle plate holes (42), however, are slightly larger in dimensions to the bottom plate holes (52), so that a small portion of the bottom plate top surface (54) remains uncovered by the middle plate (40).

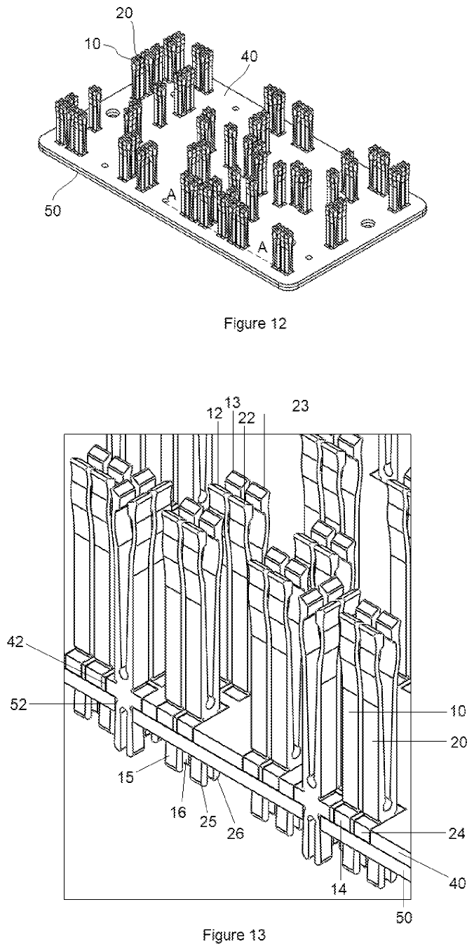

FIGS. 12 and 13 show, respectively, a perspective view and a zoomed-in cross-sectional (A-A) view of a plurality of force contacts (10) and sense contacts (20) inserted into the middle plate (40) and bottom plate (50) in an embodiment of the present invention. This is the third step in the assembly method, where pairs of contacts, one force contact (10) and one sense contact (20) in each pair, are inserted through the middle plate holes (42) and bottom plate holes (52) from a top side. The legs (15, 16) of the force contact (10) and legs (25, 26) of the sense contact (20) are threaded through predetermined middle plate holes (42) and bottom plate holes (52). The shoulders (14, 24) of each contact are just wide enough that they fit snugly within the middle plate holes (42), but are too wide to go through the bottom plate holes (52), but instead rest on the top surface (54) of the bottom plate (50). The force contact arms (12, 13) and sense contact arms (22, 23) point upwards and remain flexible.

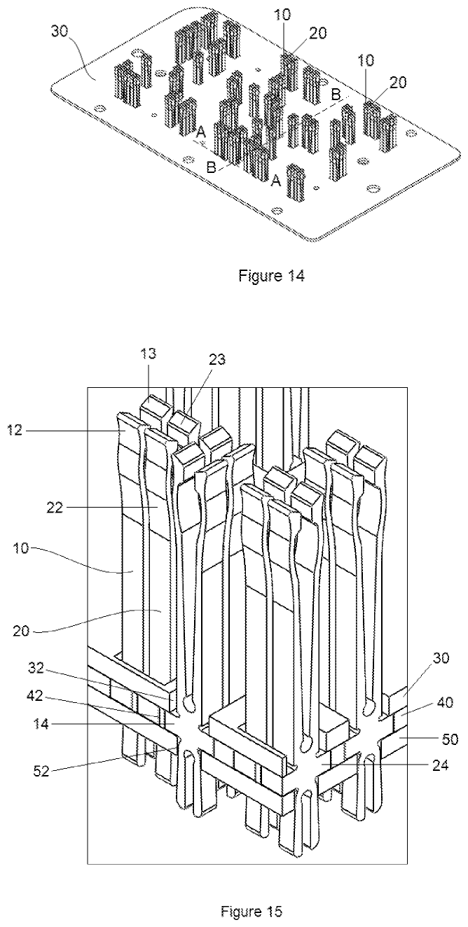

FIGS. 14 and 15 show, respectively, a perspective view and a zoomed-in cross-sectional (A-A, B-B) view of a plurality of force contacts (10), sense contacts (20), a top plate (30), middle plate (40) and bottom plate (50) in an embodiment of the present invention. This shows final step towards a fully assembled contact terminal of the present invention, with the top plate (30) being lowered onto the assembly. The top plate (30) is provided with rectangular holes (32) that correspond in position to the middle plate holes (42), but are smaller in size than the said middle plate holes (42). As the top plate (30) is lowered onto the assembly, the arms (12, 13, 22, 23) are threaded through the top plate holes (32). When the top plate (30) is flush on top of the middle plate (40), the top plate holes (32) being less wide than the shoulders (14, 24) hold and press the shoulders (14, 24) down. The top plate (30) is then secured to the bottom (50) and middle (40) plates with, say, screws or similar fastening methods. In this way, the contacts (10, 20) are held securely within the contact terminal.

With the above method of assembly, the contacts (10, 20) are able to be positioned very precisely, even though they are very close to each other. This allows the legs (15, 16, 25, 26) to be very reliably inserted into load board holes. This also means that the arms (12, 13, 22, 23) are positioned very precisely and are able to receive device pins in many states of lateral or angular deviation. Each rectangular hole (32, 42, 52) is formed using a non-contact machining technique, such as laser cutting, so that a very accurate rectangle with precise dimensions and without any machine burr or extended cutter radius is achieved.

The problem of space constraint that is derived from placing two contacts so close to each other is thus solved using the assembly method described above.

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

1. An electrical contact terminal in a testing apparatus for detachably connecting with an IC device pin, comprising:
a force contact extending along a longitudinal axis (YY) between a first and a second end and having a forked pair of arms extending towards its first end, said arms adapted to receive the device pin in between thereof and having an inward bias so as to establish a good electrical connection with the device pin, and further having a means of establishing an electrical connection with a load board of the testing apparatus, said means extending towards its second end;
a sense contact also extending along the longitudinal axis (YY) between a first and a second end and having a forked pair of arms extending towards its first end, said arms adapted to receive the device pin in between thereof and having an inward bias so as to establish a good electrical connection with the device pin, and further having a means of establishing an electrical connection with a load board of the testing apparatus, said means extending towards its second end;
whereby as the device pin is lowered towards the testing apparatus, it connects with at least one arm of the force pin and at least one arm of the sense pin.

2. An electrical contact terminal in a testing apparatus for detachably connecting with an IC device pin according to claim 1, wherein the force contact's means of establishing an electrical connection with the load board comprises a pair of legs extending towards its second end, and wherein the sense contact's means of establishing an electrical connection with the load board comprises a pair of legs extending towards its second end, said legs having an outward bias when snugly inserted into contact holes of a load board of the testing apparatus.

3. An electrical contact terminal in a testing apparatus for detachably connecting with an IC device pin according to claim 2, wherein the force contact further comprises a shoulder comprising two lateral protrusions protruding on opposite sides of the force contact and located between its first and second pair of arms, and wherein the sense contact further comprises a shoulder comprising two lateral protrusions protruding on opposite sides of the sense contact and located between its first and second pair of arms.

4. An electrical contact terminal in a testing apparatus for detachably connecting with an IC device pin according to claim 3, wherein the force and sense contact's means of establishing an electrical connection with the load board further comprises a top plate, a middle plate and a bottom plate, wherein the bottom plate is provided with holes through which holes the pair of legs, but not the shoulders can pass, and the middle plate is provided with holes sized so that the shoulders can snugly pass through, and the top plate is provided with holes through which holes the pair of arms, but not the shoulders can pass, and wherein, during an assembly of each of the force contact and sense contact, the pair of legs are inserted through the middle plate holes and into the bottom plate holes, within which their said outward bias grips the holes, and the shoulders rest on a top surface of the bottom plate and are held in lateral position within the middle plate holes, after which the top plate is lowered onto the assembly, with the top plate holes being threaded by the pair of arms, and the top plate securing the shoulders so that the contacts are held securely.

5. An electrical contact terminal in a testing apparatus for detachably connecting with an IC device pin according to claim 4, wherein the top plate holes, middle plate holes and bottom plate holes are rectangular holes and formed using non-contact machining techniques such that no machining burr is formed at the corners of the holes.

6. An electrical contact terminal in a testing apparatus for detachably connecting with an IC device pin according to claim 1, wherein each pair of arms are provided on an inside surface with a relief cavity close to their upper ends, said relief cavity allowing only a portion of the inside surface near the upper end of the arms to be in contact with the device pin.
